(19) United States
(12) Patent Application Publication
(10) Pub. No.: US 2003/0034516 A1
(43) Pub. Date: Feb. 20, 2003

(54) Structure of a non-volatile memory

(76) Inventors: Tso-Hung Fan, Pan-Chiao (TW); Wen-Jer Tsai, Hualian (TW); Tao-Cheng Lu, Kaoshiung (TW)

Correspondence Address: J.C. Patents, Inc., Suite 250, 4 Venture, Irvine, CA, 92618, US

(21) Appl. No.: 09/948,851

(22) Filed: Sep. 7, 2001

(30) Foreign Application Priority Data
Aug. 9, 2001 (TW) 90119462

(51) Int. Cl. H01L 29/76

(52) U.S. Cl. 257/314; 257/345; 257/655

(57) ABSTRACT

A structure of a non-volatile memory including a substrate with a vertical ladder channel profile (VLCP), a stacked gate structure on the substrate, and a source/drain region in the substrate beside the stacked gate structure. The vertical ladder channel profile is a profile of the dopant concentration in a first doped region directly underneath the surface of the substrate and in a second doped directly underlying the first doped region, wherein the dopant concentration in the second doped region is larger than that in the first doped region.

### CROSS-REFERENCE TO RELATED APPLICATION

This application claims the priority benefit of Taiwan application serial no. 90119462, filed Aug. 9, 2001.

### BACKGROUND OF THE INVENTION

1. Field of Invention

The present invention relates to a structure of a semiconductor device. More particularly, the present invention relates to a structure of a non-volatile memory.

2. Description of Related Art

A non-volatile memory has the ability to retain stored data even if the power source is turned off. It also has the advantages of being small in dimension, speedy in data retrieval and storage, and stable for data storage (up to 10 years). Therefore the non-volatile memory is being used more and more frequently, especially for the flash-type non-volatile memory. Since electronic devices become more powerful with time, the integration of the non-volatile memory needs to increase to enhance the data storage capacity.

In order to promote the integration of the non-volatile memory, the size of the memory cell, the gate linewidth and channel length have to be reduced. However, the short channel effect (SCE) and the drain-turn-on leakage (DTOL) become more serious as the channel length is decreased. As a consequence, the accuracy of data reading of the memory device is worsened, and the power consumption of the memory device becomes higher.

The drain-turn-on leakage is attributed to the coupling effect between the gate and the drain, which is quantified as the drain coupling ratio (DCR). When the channel length is decreased and a larger DCR is induced thereby or the bias of the drain is higher, the drain-turn-on leakage becomes larger. This is because a larger DCR or a higher bias of the drain will induce a higher electric potential on the gate, so that the sub-threshold current in the substrate under the gate is increased. Such a sub-threshold current is namely the drain-turn-on leakage.

### SUMMARY OF THE INVENTION

Accordingly, a structure of a non-volatile memory is provided, wherein the short channel effect (SCE) and the drain-turn-on leakage (DTOL) are both mitigated.

The non-volatile memory of this invention includes a substrate with a vertical ladder channel profile (VLCP), a stacked gate structure on the substrate, and a source/drain region in the substrate beside the stacked gate structure. The vertical ladder channel profile is a profile of a dopant concentration in a first doped region directly underneath the top surface of the substrate and in a second doped region directly underlying the first doped region, wherein the dopant concentration in the second doped region is higher than that in the first doped region.

Besides, in the non-volatile memory of this invention, the dopant concentration in the first doped region can be that originally in the substrate or in the well within the substrate. In another words, it may not be necessary to perform another implantation to create the first doped region.

Since the non-volatile memory provided in this invention includes a second doped region with a higher dopant concentration, short channel effect (SCE) and drain-turn-on leakage (DTOL) are both reduced, while the demonstrations of this fact are shown in the preferred embodiments of this invention. In addition, when the dopant concentration in the second doped region is higher, the drain-turn-on leakage (DTOL) is smaller. Since the short channel effect and the drain-turn-on leakage are both reduced in the non-volatile memory of this invention, the reading error does not easily occur during the reading operation and the power consumption can be decreased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 & 1A schematically illustrates a dual-cell non-volatile memory according to a preferred embodiments of the present invention, wherein FIG. 1A shows the vertical ladder channel profile (VLCP) in the substrate;

FIG. 2 is a plot diagram illustrating the drain coupling ratio (DCR) with respect to the dopant concentration N_{P} in the second doped region at various gate linewidths in the preferred embodiments of this invention;

FIG. 3 is a plot of the drain-turn-on leakage (DTOL) with respect to the gate linewidth at various dopant concentrations N_{P} in the second doped region in the preferred embodiments of this invention; and

FIG. 4 is a plot for the comparison of the threshold voltages of the non-volatile memory in the preferred embodiments of this invention and the conventional one.

### DESCRIPTION OF THE PREFERRED EMBODIMENTS

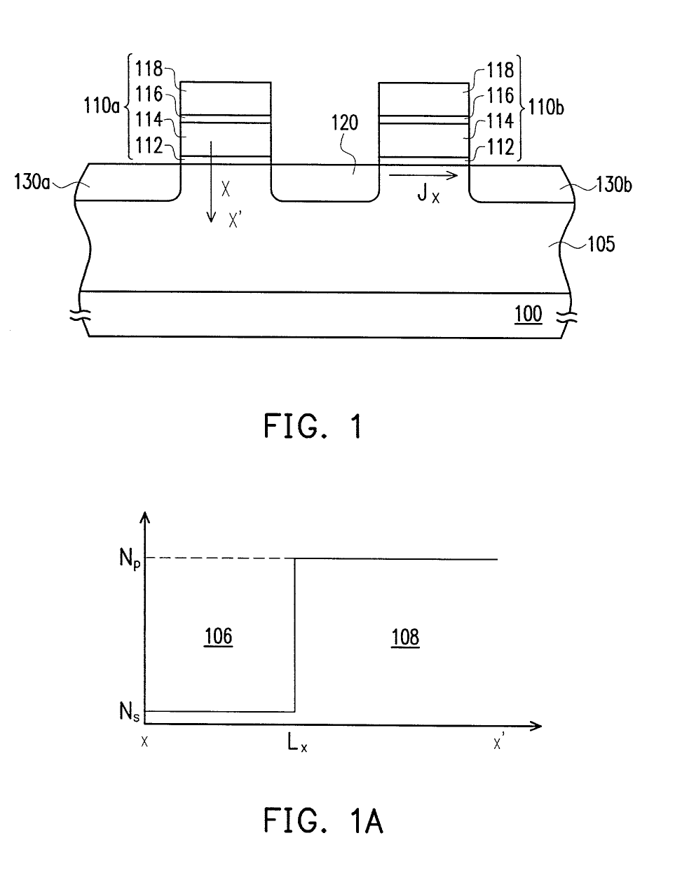

FIGS. 1 & 1A schematically illustrate a dual-cell non-volatile memory in the preferred embodiments of this invention, wherein FIG. 1A shows the vertical ladder channel profile in the substrate. The structure shown in FIG. 1 includes a substrate 100, a well 105 in the substrate 100, two stacked gate structures 110a and 110b on the substrate 100, a common drain region 120 in the substrate 100 between the two stacked gate structures 110a and 110b, and two source regions 130a and 130b in the substrate 100 on two external sides of the two stacked gate structures 110a and 110b. The stacked gate structure 110a/b consists of a tunnel layer 112, a floating gate 114, a dielectric layer 116, and a control gate 118, arranged from bottom to top. The junction depth of the common drain region 120, or the source region 130a/b ranges, for example, from 400 Å to 1000 Å.

As shown in FIG. 1A, the distribution curve of the dopant concentration (channel profile) along the trajectory x-x′ in the substrate 100 in FIG. 1 shows a vertical ladder channel profile (VLCP). The vertical ladder channel profile includes a lower dopant concentration N_{S} of a first doped region 106 and a higher dopant concentration N_{P} in a second doped region 108, wherein the first doped region 106 is directly underneath the surface of the substrate and the second doped region 108 is directly underlying the first doped region 106. The value of N_{S} can be the original dopant concentration in the well 105, which ranges from 10¹⁶/cm³ to 5×10¹⁷/cm³, for example, and N_{P}/N_{S} is preferably larger than 20. Besides, the distance Lₓ from the top surface of the substrate 100 to the boundary between the first doped region 106 and the second doped region ranges from 100 Å to 600 Å, for example. Moreover, the dopant in the second doped region 108 can be an element of III/V group with low diffusivity in order to prevent the properties of the device from being changed by the out-diffusion of the dopants in the heavily (second) doped region 108. When the conductivity of the common drain region 120 is P-type, the dopant can be antimony (Sb); while the dopant can be gallium (Ga) or indium (In) as the conductivity of the common drain region 120 is N-type.

The testing results for the dual-cell non-volatile memory in the preferred embodiment of this invention are described and explained in the following sections. The items in the test include the drain coupling ratio (DCR), the drain-turn-on leakage (DTOL), and the threshold voltage (V_{T}), wherein the DTOL is the leakage current Jₓ occurring in the channel under the stacked gate structure 110b as the channel under the stacked gate structure 110a is turned on by applying a voltage to the stacked gate structure.

Testing Results

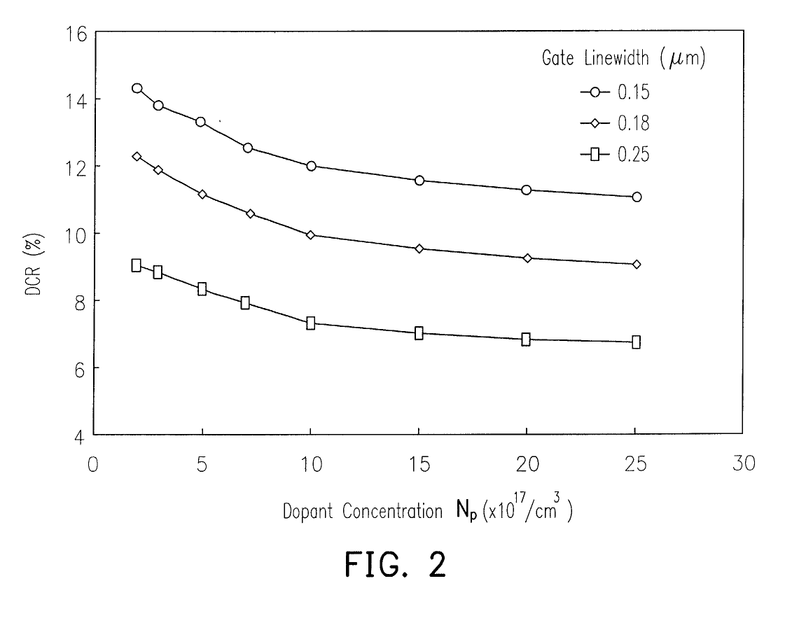

FIG. 2 is a plot of the drain coupling ratio (DCR) with respect to the dopant concentration N_{P} in the second doped region 108 at various gate linewidths in the preferred embodiments of this invention. As shown in FIG. 2 the drain coupling ratio (DCR) becomes larger as the gate linewidth decreases, and the drain coupling ratio becomes smaller as the dopant concentration N_{P} in the second doped region 108 increases. For example, if the gate linewidth is 0.15 μm, the DCR is 14.2% when N_{P} is 2×10¹⁷/cm³; while the DCR is 11% when N_{P} is 2.5×10¹⁸/cm³. In other words, the DCR is reduced by 3.2%. A smaller drain coupling ratio implies a smaller drain-turn-on leakage, which can be clearly seen from the following testing results.

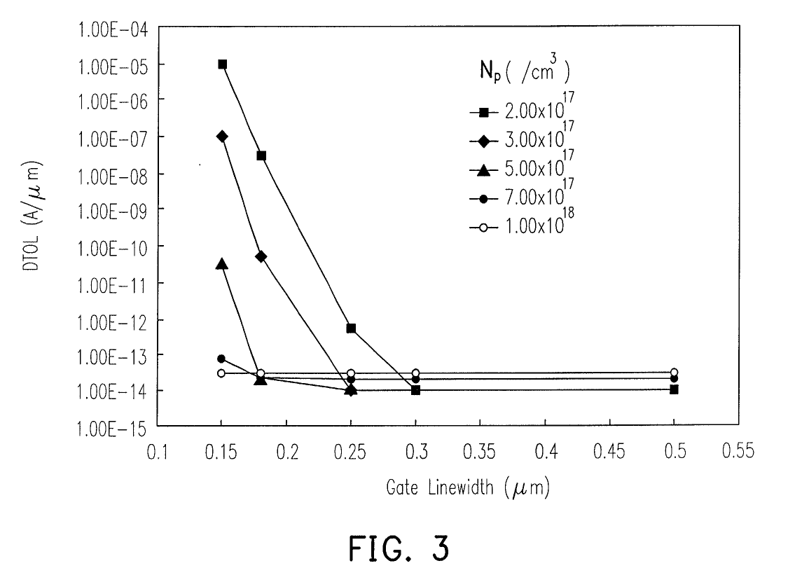

FIG. 3 is a plot of the drain-turn-on leakage (DTOL) with respect to the gate linewidth at various dopant concentrations N_{P} in the second doped region in the preferred embodiments of this invention. As shown in FIG. 3, the DTOL is larger as the gate linewidth becomes smaller, and the degree of the increase of the DTOL with the decreasing gate linewidth become smaller when the dopant concentration N_{P} in the second doped region 108 is larger. Furthermore, when N_{P} is up to 10¹⁸/cm³, the DTOL barely increases as the gate linewidth decreases.

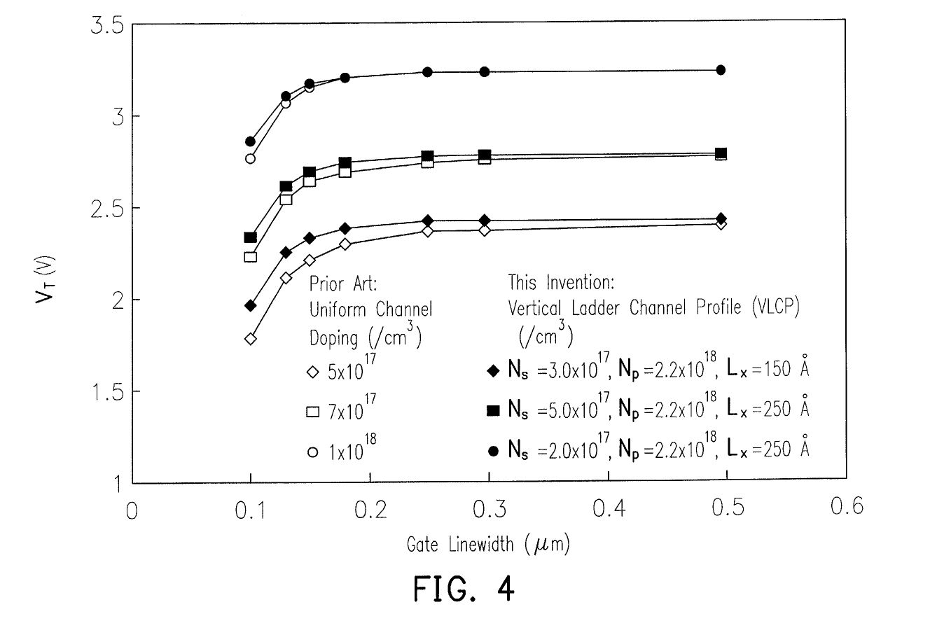

On the other hand, FIG. 4 is a plot of a comparison of the threshold voltages of the non-volatile memory in the preferred embodiments of this invention and the conventional non-volatile memory at the various linewidths. There are totally three pairs of curves plotted in FIG. 4 for comparison, wherein each pair consists of a threshold voltage curve of the non-volatile memory in this invention and that of a conventional non-volatile memory. Also, the two threshold voltages of the two non-volatile memory devices in any pair of the curves are adjusted to approximately the same when the gate linewidth is largest. As shown in FIG. 4, the threshold voltage of the non-volatile memory in this invention is always higher than that of the conventional one, which means that the short channel effect in the non-volatile memory of this invention is less severe than that in the conventional non-volatile memory.

Moreover, Table 1 shows the variations of the threshold voltages of the non-volatile memory in this invention and the conventional one as the bias of the drain is raised. As shown in Table 1, when the threshold voltages of the non-volatile memory in this invention and the conventional one are both 2.70V as the bias of the drain is close to 0V, the threshold voltages of the non-volatile memory in this invention are higher than those of the conventional non-volatile memory as the bias of the drain increases to 1V and 4V, respectively. This result also means that the short channel effect of the non-volatile memory of this invention is less severe than that of the conventional non-volatile memory.

TABLE 1

| | V_{T} (V_{d} = 0.1 V) | V_{T} (V_{d} = 1.0 V) | V_{T} (V_{d} = 4.0 V) |
|---|---|---|---|
| Conventional | 2.70 V | 2.35 V | 1.70 V |
| Present | 2.70 V | 2.50 V | 1.85 V |

In summary, it is obvious from the testing results above that the drain coupling ratio (DCR) and the drain-turn-on leakage (DTOL) in the non-volatile memory of this invention are both reduced as the dopant concentration in the second doped region increases. In addition, it can be seen from FIG. 4 and Table 1 that the extent of the drop of the threshold voltage of the non-volatile memory of the present invention is less than that of the conventional non-volatile memory as the gate linewidth reduces or as the bias of the drain increases. In other words, the non-volatile memory of the present invention has a less severe short channel effect than the conventional non-volatile memory. Since the short channel effect and the drain-turn-on leakage are both reduced in the non-volatile memory of this invention, the reading error does not easily occur during the reading process and the power consumption can be decreased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A structure of a non-volatile memory, comprising:
a substrate with a vertical ladder channel profile, wherein the vertical ladder channel profile is a profile of a dopant concentration in a first doped region directly underneath a top surface of the substrate and in a second doped region directly underlying the first doped region, and the dopant concentration in the second doped region is larger than that in the first doped region;
a stacked gate structure on the substrate; and
a source/drain region in the substrate beside the stacked gate structure.

2 The structure of claim 1, wherein the first doped region has a first dopant concentration N_{S}, the second doped region has a second dopant concentration N_{P}, and N_{P}/N_{S}>20.

3. The structure of claim 1, wherein the first doped region has a dopant concentration ranging from 10¹⁶/cm³ to 5×10¹⁷/cm³.

4. The structure of claim 1, further comprising in the substrate a well with a same conductivity type as the first or the second doped region, while the vertical ladder channel profile is located within the well

5. The structure of claim 1, wherein a distance from a boundary between the first doped region and the second doped region to the top surface of the substrate ranges from 100 Å to 600 Å.

6. The structure of claim 1, wherein a junction depth of the source/drain region ranges from 400 Å to 1000 Å.

7. The structure of claim 1, wherein a conductivity type of the source/drain region is P-type, and a dopant in the second doped region comprises antimony (Sb).

8. The structure of claim 1, wherein a conductivity type of the source/drain region is N-type, and a dopant in the second doped region comprises gallium (Ga).

9. The structure of claim 1, wherein a conductivity type of the source/drain region is N-type, and a dopant in the second doped region comprises indium (In).

10. The structure of claim 1, wherein the stacked gate structure comprises, from bottom to top, a tunnel layer, a floating gate, a dielectric layer, and a control gate.

11. A structure of a non-volatile memory, comprising:
a substrate with a vertical ladder channel profile, wherein is a profile of a dopant concentration in a first doped region directly underneath a top surface of the substrate and in a second doped region directly underlying the first doped region, and the dopant concentration in the second doped region is larger than that in the first doped region;
two stacked gate structures on the substrate,
a common drain region in the substrate between the two stacked gate structures; and
two source regions in the substrate on two external sides of the two stacked gate structures.

12. The structure of claim 11, wherein the first doped region has a first dopant concentration N_{S}, the second doped region has a second dopant concentration N_{P}, and N_{P}/N_{S}>20.

13. The structure of claim 11, wherein the first doped region has a dopant concentration ranging from about 10¹⁶/cm³ to about 5×10¹⁷/cm³.

14. The structure of claim 11, further comprising in the substrate a well with a same conductivity type as the first or the second doped region, while the vertical ladder channel profile is located within the well.

15. The structure of claim 11, wherein a distance from a boundary between the first doped region and the second doped region to the top surface of the substrate ranges from about 100 Å to about 600 Å.

16. The structure of claim 11, wherein a junction depth of the two source regions and the common drain region ranges from about 400 Å to about 1000 Å.

17. The structure of claim 11, wherein a conductivity type of the two source regions and the common drain region is P-type, and a dopant in the second doped region comprises antimony (Sb).

18. The structure of claim 11, wherein a conductivity type of the two source regions and the common drain region is N-type, and a dopant in the second doped region comprises gallium (Ga).

19. The structure of claim 11, wherein a conductivity type of the two source regions and the common drain region is N-type, and a dopant in the second doped region comprises indium (In).

20. The structure of claim 11, wherein each of the stacked gate structures comprises a tunnel layer, a floating gate, a dielectric layer, and a control gate.
